(19) United States
(12) Patent Application Publication
(10) Pub. No.: US 2021/0214845 A1
(43) Pub. Date: Jul. 15, 2021

(54) SUBSTRATE PROCESSING APPARATUS AND ROTARY DRIVE METHOD

(71) Applicant: Tokyo Electron Limited, Tokyo (JP)

(72) Inventor: Junnosuke TAGUCHI, Iwate (JP)

(21) Appl. No.: 17/128,655

(22) Filed: Dec. 21, 2020

(30) Foreign Application Priority Data
Jan. 15, 2020 (JP) 2020-004496

(51) Int. Cl. C23C 16/458; C23C 16/455; H01L 21/687

(52) U.S. Cl. CPC C23C 16/4584; H01L 21/68764; C23C 16/45544; C23C 16/4585

(57) ABSTRACT

A substrate processing apparatus includes a vacuum chamber, a rotary table disposed inside the vacuum chamber and configure to rotate, and a housing box disposed inside the vacuum chamber and configured to rotate together with the rotary table, the housing box having an inside pressure higher than in the vacuum chamber.

### BACKGROUND OF THE INVENTION

### 1. Field of the Invention

The disclosures herein relate to a substrate processing apparatus and a rotary drive method

### 2. Description of the Related Art

An apparatus as known in the art rotates a rotary table having a plurality of wafers placed thereon to cause the wafers to revolve around and repeatedly pass through areas which are arranged along a radial direction of the rotary table and to which a reactant gas is supplied, thereby forming a various type of films on the wafers (see Patent Document 1, for example). This apparatus is configured such that stages for wafer support are each rotated to cause wafer rotation while the wafers revolve around on the rotary table, thereby increasing the homogeneity of films in the circumferential direction of wafers.

The present disclosures provide a technology that reduces the generation of particles. [Patent Document 1] Japanese Laid-open Patent Publication No. 2016-96220

### SUMMARY OF THE INVENTION

According to an embodiment, a substrate processing apparatus includes a vacuum chamber, a rotary table disposed inside the vacuum chamber and configure to rotate, and a housing box disposed inside the vacuum chamber and configured to rotate together with the rotary table, the housing box having an inside pressure higher than in the vacuum chamber.

### BRIEF DESCRIPTION OF THE DRAWINGS

Other objects and further features of the present invention will be apparent from the following detailed description when read in conjunction with the accompanying drawings, in which:

FIG. 1 is a schematic drawing illustrating an example of the configuration of a substrate processing apparatus;

FIG. 2 is a cross-sectional view illustrating an example of the configuration of a deposition apparatus;

FIG. 3 is a plan view illustrating the internal configuration of the vacuum chamber of the deposition apparatus;

FIG. 4 is a perspective view illustrating positional relationships between a housing box and a rotary table in the decomposition apparatus illustrated in FIG. 2;

FIG. 5 is a cross-sectional view illustrating the internal configuration of the housing box of the deposition apparatus illustrated in FIG. 2;

FIG. 6 is a flowchart illustrating an example of the operation of a rotary drive device; and

FIG. 7 is a flowchart illustrating another example of the operation of the rotary drive device.

### DESCRIPTION OF THE PREFERRED EMBODIMENTS

In the following, embodiments of the present disclosures as non-limiting examples will be described with reference to the accompanying drawings. In the drawings, the same or corresponding members or elements are referred to by the same or corresponding reference characters, and duplicate descriptions thereof will be omitted.

### [Substrate Processing Apparatus]

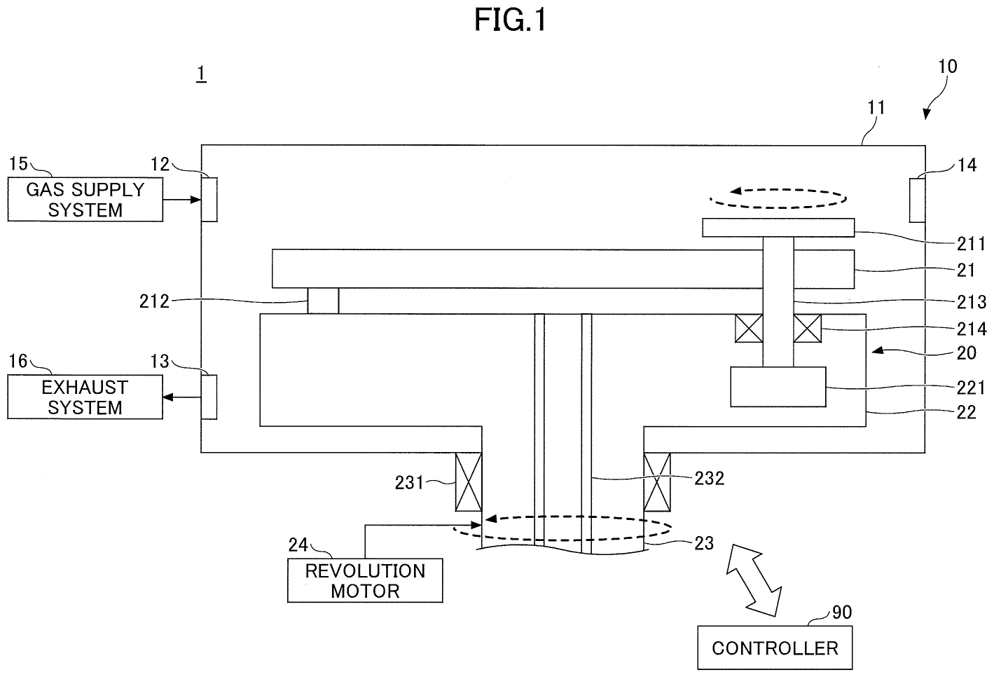

An example of the configuration of a substrate processing apparatus will be described by referring to FIG. 1. FIG. 1 is a schematic drawing illustrating an example of the configuration of a substrate processing apparatus.

The substrate processing apparatus 1 includes a processing unit 10, a rotary drive device 20, and a controller 90.

The processing unit 10 is configured to perform semiconductor manufacturing processes on wafers. The semiconductor manufacturing processes include heat treatment, film deposition, and etching, for example. The processing unit 10 includes a vacuum chamber 11, a gas inlet 12, a gas outlet 13, and a loading port 14.

The vacuum chamber 11 is configured to enable the decompression of the inner space. The vacuum chamber 11 is configured such that a plurality of substrates are placeable in the inner space. The vacuum chamber 11 may alternatively be configured such that a single substrate is placeable in the inner space. The substrates may be semiconductor wafers, for example.

The vacuum chamber 11 has the gas inlet 12. The gas inlet 12 may be a gas nozzle or a showerhead, for example. Gases for semiconductor manufacturing processes are introduced into the inner space of the vacuum chamber 11 from a gas supply system 15 through the gas inlet 12. The gases include at least one of a deposition gas, an etching gas, and a separation gas, for example.

The vacuum chamber 11 has the gas outlet 13. The gas outlet 13 may be an opening formed through the wall of the vacuum chamber 11, for example. The gases introduced into the vacuum chamber 11 are evacuated through the gas outlet 13 by an exhaust system 16.

The vacuum chamber 11 has the loading port 14. The loading port 14 is an opening for loading substrates into the vacuum chamber 11 and for unloading substrates from the vacuum chamber 11. The loading port 14 is opened and closed by a gate valve (not shown).

The gas supply system 15 introduces gases for semiconductor manufacturing processes into the inner space of the vacuum chamber 11 through the gas inlet 12. The gas supply system 15 includes gas supply sources, gas lines, valves, and flow controllers, for example.

The exhaust system 16 evacuates gases introduced into the vacuum chamber 11 to decompress the inner space of the vacuum chamber 11. The exhaust system 16 includes an exhaust gas line, a valve, and a vacuum pump, for example.

The rotary drive device 20 includes a rotary table 21, a housing box 22, a rotating shaft 23, and a revolution motor 24.

The rotary table 21 is provided in the vacuum chamber 11. The rotary table 21 is configured to rotate around the center of the vacuum chamber 11. The rotary table 21 has a disc shape, for example. A plurality of stages 211 are arranged in the direction of rotation (i.e., in the circumferential direction) on the upper surface of the rotary table 21. The rotary table 21 is connected to the housing box 22 via connectors 212.

Each stage 211 is configured to have a substrate (not shown) placed thereon. Each stage 211, which is connected to the rotation motor 221 through a rotating shaft 213, is configured to rotate relative to the rotary table 21.

The connectors 212 connect the lower surface of the rotary table 21 and the upper surface of the housing box 22, for example. The connectors 212 are arranged in a circumferential direction of the rotary table 21, for example. The connectors 212 may have a through hole formed therein to allow a temperature sensor, various probes, or the like to be introduced into the inside of the rotary table 21 from the housing box 22.

The rotating shaft 213, which connects the lower surface of the stage 211 and the rotation motor 221 contained in the housing box 22, transmits power of the rotation motor 221 to the stage 211. The rotating shaft 213 is configured to rotate around the center of the stage 211. The rotating shaft 213 is disposed to extend through the ceiling of the housing box 22 and the rotary table 21. A seal 214 is disposed in the through hole in the ceiling of the housing box 22 to ensure airtightness inside the housing box 22. The seal 214 includes a magnetic fluid seal, for example.

The housing box 22 is provided in the vacuum chamber 11. The housing box 22, which is connected to the rotary table 21 through the connectors 212, is configured to rotate together with the rotary table 21. The inside of the housing box 22 is isolated from the inner space of the vacuum chamber 11, and is maintained at a higher pressure than in the vacuum chamber 11, e.g., at the atmospheric pressure. The housing box 22 stores mechanical parts such as rotation motors 221.

The rotation motor 221, which is connected to the lower end of the rotating shaft 213, serves as a drive unit that rotates the stage 211 relative to the rotary table 21 through the rotating shaft 213 for rotating the substrate. The rotation motor 221 may be a servomotor, for example.

The rotating shaft 23 is fixedly connected to the housing box 22. The rotating shaft 23 may instead be fixed to the rotary table 21. The rotating shaft 23 and the housing box 22 may be integrated into a seamless unit, or may be distinct parts. The rotating shaft 23 is disposed to extend through the bottom of the vacuum chamber 11. A seal 231 is disposed at the through hole in the bottom of the vacuum chamber 11 to ensure airtightness inside the vacuum chamber. The seal 231 includes a magnetic fluid seal, for example. The rotating shaft 23 has a fluid path 232 formed therethrough for introducing a fluid into the housing box 22. Examples of the fluid include atmosphere, coolant, and the like.

The revolution motor 24 rotates the rotary table 21 relative to the vacuum chamber 11 via the rotating shaft 23, thereby causing the substrates to revolve around. As the rotating shaft 23 rotates, the housing box 22 rotates together with the rotary table 21. Namely, the rotary table 21, the housing box 22, and the rotating shaft 23 rotate as one consolidated unit.

The controller 90 controls the individual parts of the substrate processing apparatus 1. The controller 90 may be a computer, for example. Computer programs for functioning of respective parts of the substrate processing apparatus 1 are stored in a storage medium. Examples of the storage medium include a flexible disk, a compact disk, a hard disk drive, a flash memory, a DVD, and the like.

As described above, the substrate processing apparatus 1 includes the vacuum chamber 11, the rotary table 21 rotatably disposed inside the vacuum chamber 11, and the housing box 22, which has an inside pressure higher than the vacuum chamber 11, and which rotates together with the rotary table 21 inside the vacuum chamber 11. With this arrangement, when the stage 211 to rotate relative to the rotary table 21 is provided within the vacuum chamber 11, the rotation motor 221 for rotating the stage 211 may be disposed inside the housing box 22, which is isolated from the vacuum chamber 11. Particles and the like generated by mechanical contact occurring at the bearings and the like in the rotation motor 221 are thus confined within the housing box 22. This arrangement prevents the particles from entering a process area. Moreover, the rotation motors 221 do not come in contact with gases introduced into the vacuum chamber 11, which serves to prevent corrosion caused by the gases.

Further, the rotation motor 221 is not disposed in the decompressed environment inside the vacuum chamber 11, but disposed in the designated area within the substrate processing device, i.e., in the housing box 22 which may be maintained in the same environment as in a clean room, for example. This ensures the stable functioning of the rotation motor 221. As a result, the stage 211 driven by the rotation motor 221 is able to rotate with high accuracy.

### Specific Example of Configuration of Substrate Processing Apparatus

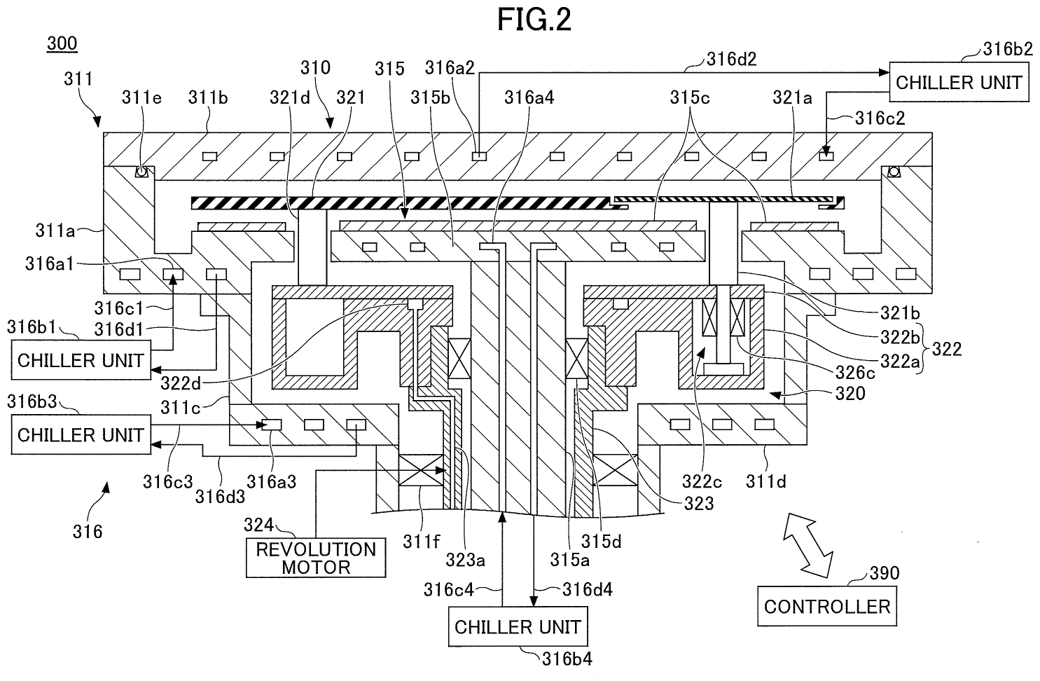

As a specific example of the configuration of the substrate processing apparatus 1, a deposition apparatus 300 for forming a film on substrates will be described by referring to FIG. 2 through FIG. 5.

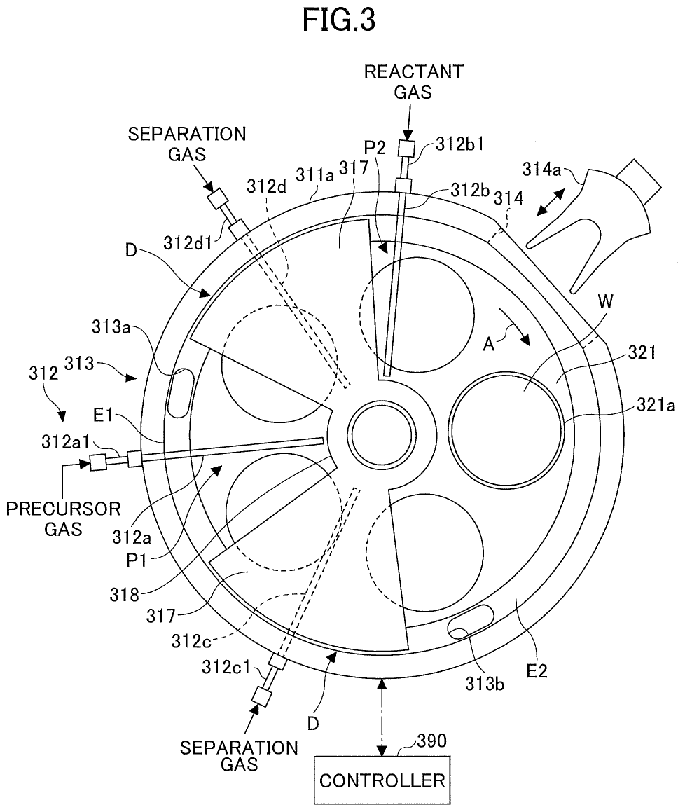

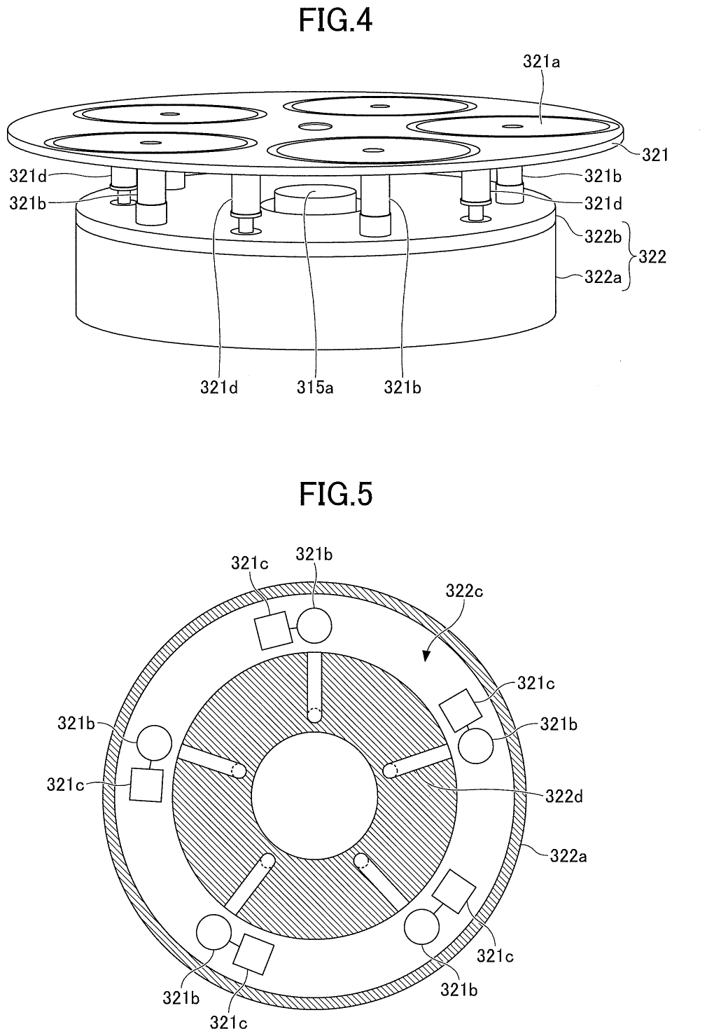

FIG. 2 is a cross-sectional view illustrating an example of the configuration of a deposition apparatus. FIG. 3 is a plan view illustrating the internal configuration of the vacuum chamber of the deposition apparatus. In FIG. 3, the illustration of a top plate is omitted for the sake of convenience of explanation. FIG. 4 is a perspective view illustrating positional relationships between a housing box and a rotary table in the decomposition apparatus illustrated in FIG. 2. FIG. 5 is a cross-sectional view illustrating the internal configuration of the housing box of the deposition apparatus illustrated in FIG. 2.

The deposition apparatus 300 includes a processing unit 310, a rotary drive device 320, and a controller 390.

The processing unit 310 is configured to perform film deposition for forming a film on substrates. The processing unit 310 includes a vacuum chamber 311, a gas inlet 312, a gas outlet 313, a loading port 314, a heating unit 315, and chiller units 316.

The vacuum chamber 311 is configured to enable the decompression of the inner space. The vacuum chamber 311, which has a flat shape with a generally circular plane figure, has a plurality of substrates disposed therein. The substrates may be semiconductor wafers, for example. The vacuum chamber 311 includes a body 311a, a top plate 311b, a sidewall 311c and a bottom plate 311d (see FIG. 2). The body 311a has a cylindrical shape. The top plate 311b is detachably disposed on the top surface of the body 311a to ensure airtightness with a seal 311e. The sidewall 311c, which is connected to the lower surface of the body 311a, has a cylindrical shape. The bottom plate 311d is disposed beneath the bottom surface of the sidewall 311c in such a manner as to ensure airtightness.

The gas inlet 312 includes a precursor gas nozzle 312a, a reactant gas nozzle 312b, and separation gas nozzles 312c and 312d (FIG. 3). The precursor gas nozzle 312a, the reactant gas nozzle 312b, and the separation gas nozzles 312c and 312d are arranged above the rotary table 321 at spaced intervals in the circumferential direction (i.e., the direction indicated by an arrow A in FIG. 3) of the vacuum chamber 311. In the illustrated example, the separation gas nozzle 312c, the precursor gas nozzle 312a, the separation gas nozzle 312d, and the reactant gas nozzle 312b are arranged clockwise (i.e., in the direction of rotation of the rotary table 321) in the order named from the loading port 314. Gas inlet ports 312a1, 312b1, 312c1, 312d1 (FIG. 3), which are the proximal end of the precursor gas nozzle 312a, the reactant gas nozzle 312b, and the separation gas nozzles 312c and 312d, are fixedly attached to the outer perimeter wall of the body 311a. The precursor gas nozzle 312a, the reactant gas nozzle 312b, and the separation gas nozzles 312c and 312d extend from the outer perimeter wall of the vacuum chamber 311 to the inner space of the vacuum chamber 311, and are mounted so as to extend horizontally in the radial direction of the body 311a in parallel to the rotary table 321. The precursor gas nozzle 312a, the reactant gas nozzle 312b, and the separation gas nozzles 312c and 312d are made of quartz, for example.

The precursor gas nozzle 312a is connected to a precursor gas source (not shown) via a pipe, a flow controller, and the like (not shown). As a separation gas, a silicon containing gas or a metal containing gas may be used, for example. The precursor gas nozzle 312a has a plurality of outlet holes (not shown) facing toward the rotary table 321 and arranged at spaced intervals in the longitudinal direction of the precursor gas nozzle 312a. The area under the precursor gas nozzle 312a is a precursor gas adsorption region P1 for adsorbing a precursor gas to a substrate W.

The reactant gas nozzle 312b is connected to a reactant gas source (not shown) via a pipe, a flow controller, and the like (not shown). As a reactant gas, an oxide gas or a nitride gas may be used, for example. The reactant gas nozzle 312b has a plurality of outlet holes (not shown) facing toward the rotary table 321 and arranged at spaced intervals in the longitudinal direction of the reactant gas nozzle 312b. The area under the reactant gas nozzle 312b is a reactant gas supply region P2 in which the precursor gas adsorbed to the substrate W in the precursor gas adsorption region P1 is oxidized or nitrogenized.

The separation gas nozzles 312c and 312d are each connected to a separation gas source (not shown) via a pipe, a flow controlling valve, and the like (not shown). An inert gas such as argon (Ar) gas or nitrogen (N₂) gas may be used as a separation gas, for example. The separation gas nozzles 312c and 312d each have a plurality of outlet holes (not shown) facing toward the rotary table 321 and arranged at spaced intervals in the longitudinal direction of the separation gas nozzles 312c and 312d.

As illustrated in FIG. 3, two circle sector parts 317 are provided in the vacuum chamber 311. The circle sector parts 317 are mounted on the back surface of the top plate 311b to protrude toward the rotary table 321 so as to constitute separation regions D together with the respective separation gas nozzles 312c and 312d. The circle sector parts 317 each have a fan-shaped plane shape with the distal end thereof being arc-shaped and the proximal end being connected to a protrusion 318, and are each disposed such that the arc-shaped distal end closely follow the inner perimeter wall of the body 311a of the vacuum chamber 311.

The gas outlet 313 includes a first outlet 313a and a second outlet 313b (see FIG. 3). The first outlet 313a is formed at the bottom of a first exhaust region E1 communicating with the precursor gas adsorption region P1. The second outlet 313b is formed at the bottom of a second exhaust region E2 communicating with the reactant gas supply region P2. The first outlet 313a and the second outlet 313b are connected to an exhaust device (not shown) via exhaust lines (not shown).

The loading port 314 is situated on the sidewall of the vacuum chamber 311 (see FIG. 3). At the loading port 314, the substrate W is transferred between the rotary table 321 in the vacuum chamber 311 and a transfer arm 314a external to the vacuum chamber 311. The loading port 314 is opened and closed by a gate valve (not shown).

A heating unit 315 includes a stationary shaft 315a, a heater support 315b, and a heater 315c (see FIG. 2).

The stationary shaft 315a has a cylindrical shape that has a center axis thereof coinciding with the center of the vacuum chamber 311. The stationary shaft 315a is disposed inside the rotating shaft 323 to extend through the bottom plate 311d of the vacuum chamber 311. A seal 315d is disposed between the outer perimeter wall of the stationary shaft 315a and the inner perimeter wall of the rotating shaft 323. This arrangement allows the rotating shaft 323 to rotate relative to the stationary shaft 315a while maintaining airtightness inside the vacuum chamber 311. The seal 315d includes a magnetic fluid seal, for example.

The heater support 315b, which is secured to the top of the stationary shaft 315a, has a disc shape. The heater support 315b supports the heater 315c.

The heater 315c is provided on the upper surface of the heater support 315b. The heater 315c may be provided on the body 311a and on the top plate 311b, in addition to the upper surface of the heater support 315b. The heater 315c receives power from a power supply (not shown) to generate heat, thereby heating the substrate W.

The chiller units 316 include fluid paths 316a1 through 316a4, chiller units 316b1 through 316b4, inlet lines 316c1 through 316c4, and outlet lines 316d1 through 316d4. The fluid paths 316a1, 316a2, 316a3, and 316a4 are formed inside the body 311a, the top plate 311b, the bottom plate 311d, and the heater support 315b, respectively. The chiller units 316b1 through 316b4 supply a temperature control fluid. The temperature control fluids flowing out of the chiller units 316b1 through 316b4 flow sequentially through the inlet lines 316c1 through 316c4, the fluid paths 316a1 through 316a4, and the outlet lines 316d1 through 316d4, respectively, thereby to circulate. This arrangement adjusts the temperature of the body 311a, the top plate 311b, the bottom plate 311d, and the heater support 315b. Water, a fluorine-based fluid such as Galden (registered trademark), or the like may be used as the temperature control fluid.

The rotary drive device 320 includes a rotary table 321, a housing box 322, a rotating shaft 323, and a revolution motor 324.

The rotary table 321, which is disposed inside the vacuum chamber 311, has a rotation center coinciding with the center of the vacuum chamber 311. The rotary table 321 has a disc shape, for example, and is made of quartz. A plurality of stages 321a (e.g., five stages) are arranged in the direction of rotation (i.e., in the circumferential direction) on the upper surface of the rotary table 321. The rotary table 321 is connected to the housing box 322 via connectors 321d.

Each stage 321a has a disc shape slightly larger than the substrate W, and is made of quartz, for example. Each stage 321a is configured to have a substrate W placed thereon. The substrates W may be semiconductor wafers, for example. Each stage 321a, which is connected to a rotation motor 321c through a rotating shaft 321b, is configured to rotate relative to the rotary table 321.

The rotating shaft 321b, which connects the lower surface of the stage 321a and the rotation motor 321c contained in the housing box 322, transmits power of the rotation motor 321c to the stage 321a. The rotating shaft 321b is configured to rotate around the center of the stage 321a. The rotating shaft 321b is disposed to extend through the ceiling 322b of the housing box 322 and the rotary table 321. A seal 326c is disposed at the through hole in the ceiling 322b of the housing box 322 to ensure airtightness inside the housing box 322. The seal 326c includes a magnetic fluid seal, for example.

The rotation motor 321c rotates the stage 321a relative to the rotary table 21 through the rotating shaft 321b, thereby causing the substrate to rotate. The rotation motor 321c may be a servomotor, for example.

The connectors 321d connect the lower surface of the rotary table 321 and the upper surface of the housing box 322, for example. The connectors 321d are arranged in a circumferential direction of the rotary table 321, for example.

The housing box 322 is disposed under the rotary table 321 in the vacuum chamber 311. The housing box 322, which is connected to the rotary table 321 through the connectors 321d, is configured to rotate together with the rotary table 321. The housing box 322 may be configured to move up and down inside the vacuum chamber 311 by means of an elevating mechanism (not shown). The housing box 322 includes a body 322a and a ceiling 322b.

The body 322a, which has an upwardly open recess, extends in the direction of rotation of the rotary table 321 to form an annular shape.

The ceiling 322b is disposed on the top of the body 322a to cover the opening of the recess in the body 322a. The body 322a and the ceiling 322b together form a storage part 322c that provides a space isolated from the inner space of the vacuum chamber 311.

The storage part 322c, which has a rectangular cross-sectional shape, extends in the direction of rotation of the rotary table 321 to form an annular shape. The storage part 322c houses the rotation motors 321c. The body 322a has a communication part 322d formed therein through which the storage part 322c communicates with the outside of the deposition apparatus 300. With this arrangement, outside air is introduced into the storage part 322c from the outside of the deposition apparatus 300, which cools the inside of the storage part 322c and also maintains an atmospheric pressure therein.

The rotating shaft 323 is fixedly connected to the lower part of the housing box 322. The rotating shaft 323 is disposed to extend through the bottom plate 311d of the vacuum chamber 311. The rotating shaft 323 transmits the power of the revolution motor 324 to the rotary table 321 and the housing box 322 to rotate the rotary table 321 and the housing box 322 together. A seal 311f is disposed at the through hole in the bottom plate 311d of the vacuum chamber 311 to ensure airtightness inside the vacuum chamber 311. The seal 311f includes a magnetic fluid seal, for example.

The rotating shaft 323 has through holes 323a formed therein. A through hole 323a is connected to the communication part 322d of the housing box 322 to serve as a fluid path for introducing air into the housing box 322. The through holes 323a also function as wiring ducts for introducing power lines and signal lines for driving the rotation motors 321c into the housing box 322. The through holes 323a are provided in a number equal to the number of rotation motors 321c.

The controller 390 controls the individual parts of the deposition apparatus 300. The controller 390 may be a computer, for example. Computer programs for functioning of respective parts of the deposition apparatus 300 are stored in a storage medium. Examples of the storage medium include a flexible disk, a compact disk, a hard disk drive, a flash memory, a DVD, and the like.

### [Operation of Rotary Drive Device]

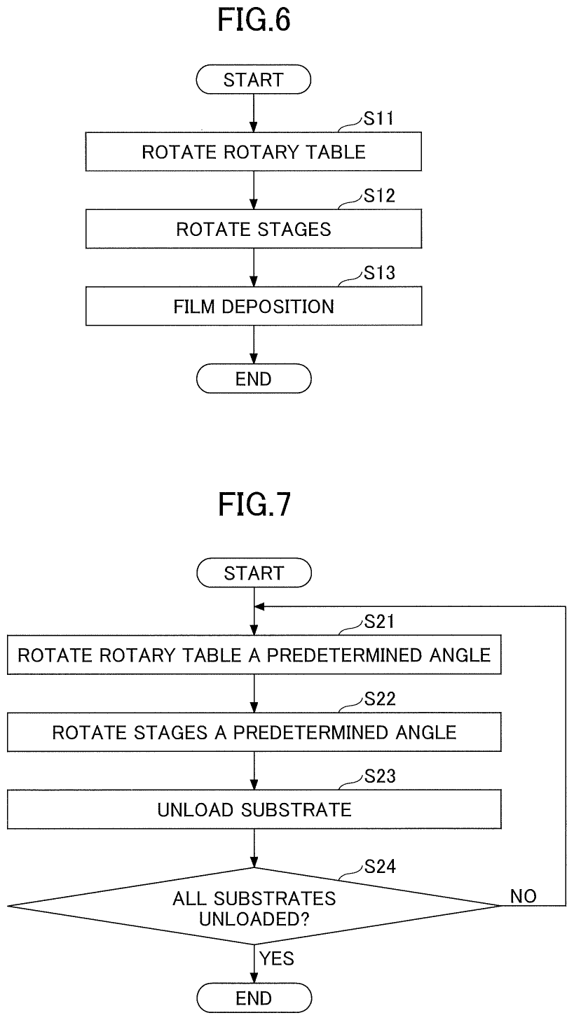

An example of the operation of the rotary drive device 320 (i.e., rotary drive method) will be described by referring to FIG. 6. FIG. 6 is a flowchart illustrating an example of the operation of the rotary drive device 320.

In the following, a description will be made of an example in which the controller 390 controls the deposition apparatus 300 to form a film by atomic layer deposition (ALD) on a substrate on the stage 321a while rotating the rotary table 321 and the stage 321a. The rotary drive method illustrated in FIG. 6 includes steps S11 through S13.

In step S11, the controller 390 controls the revolution motor 324 to rotate the rotary table 321. This causes the substrates W on the plurality of stages 321a arranged in the circumferential direction of the rotary table 321 to revolve around. The rotation rate of the rotary table 321 may be 1 to 500 rpm, for example.

In step S12, the controller 390 controls the rotation motors 321c to rotate, relative to the rotary table 321, the stages 321a arranged in the circumferential direction of the rotary table 321. Each of the substrates W mounted on the respective stages 321a thus rotates around its center. The rotation rate of the stages 321a may be 1 to 30 rpm, for example.

In step S13, the controller 390 controls the processing unit 310 to perform a film deposition process with respect to the substrates W. The controller 390 supplies a precursor gas to the precursor gas adsorption region P1 through the precursor gas nozzle 312a and a reactant gas to the reactant gas supply region P2 through the reactant gas nozzle 312b while supplying a separation gas to the separation regions D through the separation gas nozzles 312c and 312d, for example. With this arrangement, a film is deposited by ALD on the surfaces of the substrates W when the substrates W mounted on the stages 321a of the rotary table 321 repeatedly pass through the precursor gas adsorption region P1 and the reactant gas supply region P2.

With the rotary drive method noted above, each of the substrates W mounted on the stages 321a of the rotary table 321 is caused to pass repeatedly through the precursor gas adsorption region P1 and the reactant gas supply region P2 while rotate around its center, so that a film is deposited by ALD on the surfaces of the substrates W. This improves the homogeneity of the film in the circumferential direction of a substrate W.

According to the rotary drive method noted above, the rotation motors 321c for rotating the stages 321a are disposed in the inner space of the housing box 322 isolated from the vacuum chamber 311. Particles and the like generated by mechanical contact occurring at the bearings and the like in the rotation motors 321c are thus confined within the housing box 322. This arrangement prevents the particles from entering a process area. Moreover, the rotation motors 321c do not come in contact with precursor gases and reactant gases introduced into the vacuum chamber 311, which serves to prevent corrosion of the rotation motors 321c caused by the precursor gases and reactant gases.

Further, the rotation motors 321c are not disposed in the decompressed environment inside the vacuum chamber 311, but disposed in the designated areas within the deposition apparatus 300, i.e., in the housing box 322 which may be maintained in the same environment as in a clean room, for example. This ensures the stable functioning of the rotation motors 321c. As a result, the stages 321a driven by the rotation motors 321c are able to rotate with high accuracy.

Another example of the operation of the rotary drive device 320 (i.e., rotary drive method) will be described by referring to FIG. 7. FIG. 7 is a flowchart illustrating another example of the operation of the rotary drive device 320.

In the following, a description will be directed to an example in which the controller 390 controls the rotary drive device 320 to rotate the rotary table 321 and the stages 321a, and then to unload the substrates W mounted on the stages 321a of the rotary table 321 to the outside of the vacuum chamber 311. The rotary drive method illustrated in FIG. 7 is performed after the film deposition process with respect to the substrates W mounted on the stages 321a is completed, for example. The rotary drive method illustrated in FIG. 7 includes steps S21 through S24.

In step S21, the controller 390 controls the revolution motor 324 to rotate the rotary table 321a predetermined angle such that one of the plurality of stages 321a moves to a position alongside the loading port 314.

In step S22, the controller 390 controls a rotation motor 321c to rotate the stage 321a having moved to the position alongside the loading port 314, thereby rotating the substrate W mounted on the stage 321a to align the substrate W in the rotation direction.

In step S23, the controller 390 opens the gate valve, and inserting the transfer arm 314a through the loading port 314 to unload the substrate W mounted on the stage 321a located alongside the loading port 314.

In step S24, the controller 390 checks whether all of the substrates W mounted on the stages 321a have been unloaded. In step S24, the controller 390 terminates the process upon determining that the unloading of all the substrates W has been completed. Upon determining in step S24 that the unloading of all the substrates W has not been completed, the controller 390 returns the process to step S21.

According to the rotary drive method described above, when the time has come to unload the substrate W for which film deposition has been completed, the rotary table 321 is rotated, and the stages 321a are also rotated, followed by unloading the substrates W mounted on the stages 321a of the rotary table 321 to the outside of the vacuum chamber 11. With this arrangement, the substrates W may be unloaded while the rotational position is aligned.

According to the rotary drive method noted above, the rotation motors 321c for rotating the stages 321a are disposed in the inner space of the housing box 322 isolated from the vacuum chamber 311. Particles and the like generated by mechanical contact occurring at the bearings and the like in the rotation motors 321c are thus confined within the housing box 322. This arrangement prevents the particles from entering a process area. Moreover, the rotation motors 321c do not come in contact with gases introduced into the vacuum chamber 311, which serves to prevent corrosion caused by the gases.

Further, the rotation motors 321c are not disposed in the decompressed environment inside the vacuum chamber 311, but disposed in the designated areas within the deposition apparatus 300, i.e., in the housing box 322 which may be maintained in the same environment as in a clean room, for example. This ensures the stable functioning of the rotation motors 321c. As a result, the stages 321a driven by the rotation motors 321c are able to rotate with high accuracy.

The embodiments disclosed herein should be regarded as examples only and as non-limiting in all aspects. The embodiments described heretofore may have at least a part thereof removed, replaced, or modified without departing from the spirit and scope of the claims attached hereto.

The embodiments described heretofore have been directed to an example in which the five stages 321a are provided on the rotary table 321, but the present disclosures are not limited to such an example. The number of stages 321a may be 4 or less, or may be 6 or more.

The embodiments described heretofore have been directed to an example in which the processing unit 310 includes the vacuum chamber 311, the gas inlet 312, the gas outlet 313, the loading port 314, the heating unit 315, and the chiller units 316, but the present disclosures are not limited to such an example. For example, the processing unit 310 may further include a plasma generator for generating plasma to activate various gases supplied to the vacuum chamber 311.

The embodiments described heretofore have been directed to an example in which the housing box 322 is situated under the rotary table 321, but the present disclosures are not limited to such an example. For example, the housing box 322 may alternatively be disposed over the rotary table 321.

According to at least one embodiment, the generation of particles is reduced.

The present application is based on and claims priority to Japanese patent application No. 2020-004496 filed on Jan. 15, 2020, with the Japanese Patent Office, the entire contents of which are hereby incorporated by reference.

What is claimed is:

1. A substrate processing apparatus comprising:
a vacuum chamber;
a rotary table disposed inside the vacuum chamber and configure to rotate; and
a housing box disposed inside the vacuum chamber and configured to rotate together with the rotary table, the housing box having an inside pressure higher than in the vacuum chamber.

2. The substrate processing apparatus as claimed in claim 1, wherein pressure inside the housing box is atmospheric pressure.

3. The substrate processing apparatus as claimed in claim 1, wherein the housing box is disposed under the rotary table.

4. The substrate processing apparatus as claimed in claim 1, further comprising a plurality of connectors that are arranged in a circumferential direction of the rotary table and that connect the rotary table and the housing box.

5. The substrate processing apparatus as claimed in claim 1, further comprising:
a plurality of stages arranged in a circumferential direction of the rotary table and configured to support substrates placed on an upper surface thereof; and
a plurality of drive units disposed inside the housing box and configured to rotate the stages relative to the rotary table.

6. The substrate processing apparatus as claimed in claim 5, further comprising rotating shafts connecting the stages and the drive units, and configured to transmit power of the drive units to the stages.

7. The substrate processing apparatus as claimed in claim 1, wherein the housing box includes a storage part extending in a direction of rotation of the rotary table to form an annular shape, the storage part having a rectangular cross-sectional shape at a cross section perpendicular to a circumferential direction of the annular shape.

8. The substrate processing apparatus as claimed in claim 7, wherein the housing box includes a communication part communicating with the storage part to supply fluid to the storage part.

9. The substrate processing apparatus as claimed in claim 8, wherein the fluid includes air.

10. A rotary drive method comprising:
rotating a rotary table and a housing box together in a vacuum chamber, the housing box having an inside pressure higher than in the vacuum chamber; and
rotating stages relative to the rotary table by use of a plurality of drive units disposed inside the housing box, the stages being arranged in a circumferential direction of the rotary table and configured to support substrates placed on an upper surface thereof.

11. The substrate processing apparatus as claimed in claim 2, wherein the housing box is disposed under the rotary table.

12. The substrate processing apparatus as claimed in claim 11, further comprising a plurality of connectors that are arranged in a circumferential direction of the rotary table and that connect the rotary table and the housing box.

13. The substrate processing apparatus as claimed in claim 12, further comprising:
a plurality of stages arranged in the circumferential direction of the rotary table and configured to support substrates placed on an upper surface thereof; and
a plurality of drive units disposed inside the housing box and configured to rotate the stages relative to the rotary table.

14. The substrate processing apparatus as claimed in claim 13, further comprising rotating shafts connecting the stages and the drive units, and configured to transmit power of the drive units to the stages.

15. The substrate processing apparatus as claimed in claim 14, wherein the housing box includes a storage part extending in a direction of rotation of the rotary table to form an annular shape, the storage part having a rectangular cross-sectional shape at a cross section perpendicular to a circumferential direction of the annular shape.

16. The substrate processing apparatus as claimed in claim 15, wherein the housing box includes a communication part communicating with the storage part to supply fluid to the storage part.

17. The substrate processing apparatus as claimed in claim 16, wherein the fluid includes air.
